(19) United States
(12) Patent Application Publication
(10) Pub. No.: US 2012/0033696 A1
(43) Pub. Date: Feb. 9, 2012

(54) SEMICONDUCTOR LASER APPARATUS AND OPTICAL APPARATUS

(75) Inventors: Nobuhiko HAYASHI, Osaka-shi (JP); Hideki YOSHIKAWA, Takarazuka-shi (JP); Keiichi KURAMOTO, Kadoma-shi (JP)

(73) Assignee: SANYO ELECTRIC CO., LTD., Moriguchi-shi (JP)

(21) Appl. No.: 13/191,847

(22) Filed: Jul. 27, 2011

(30) Foreign Application Priority Data
Aug. 4, 2010 (JP) 2010-175698
Sep. 13, 2010 (JP) 2010-203861

(51) Int. Cl. H01S 5/022

(52) U.S. Cl. 372/43.01

(57) ABSTRACT

This semiconductor laser apparatus includes a package having sealed space inside and a semiconductor laser chip arranged in the sealed space. The package has a first member and a second member bonded to each other with an adhesive, a covering agent made of an ethylene-vinyl alcohol copolymer is formed on a bonded region of the first member and the second member in the sealed space, and the adhesive is covered with the covering agent.

### CROSS-REFERENCE TO RELATED APPLICATIONS

The priority application numbers JP2010-175698, Semiconductor Laser Apparatus and Optical Apparatus, Aug. 4, 2010, Nobuhiko Hayashi et al., and JP2010-203861, Semiconductor Laser Apparatus and Optical Apparatus, Sep. 13, 2010, Nobuhiko Hayashi et al., upon which this patent application is based are hereby incorporated by reference.

### BACKGROUND OF THE INVENTION

1. Field of the Invention

The present invention relates to a semiconductor laser apparatus and an optical apparatus, and more particularly, it relates to a semiconductor laser apparatus comprising a package sealing a semiconductor laser chip and an optical apparatus employing the same.

2. Description of the Background Art

A blue-violet semiconductor laser apparatus emitting a laser beam having a wavelength of about 405 nm has been put into practice as a light source for a Blu-ray disc. This blue-violet semiconductor laser apparatus includes a package sealing a semiconductor laser chip. Such a semiconductor laser apparatus is disclosed in Japanese Patent Laying-Open No. 2004-22918, for example.

In a semiconductor laser apparatus disclosed in Japanese Patent Laying-Open No. 2004-22918, a semiconductor laser chip is hermetically sealed with a package constituted by a metal stem and a container (cap). A glass window through which a laser beam is emitted is mounted on this cap. This glass window is mounted through low-melting-point glass having a thermal expansion coefficient close to a thermal expansion coefficient of metal in order to hermetically seal the package. A lead wire is mounted to the stem so as to pass through the package, and the stem and the lead wire are electrically insulated from each other. In order to hermetically seal a portion where this lead wire passes through the stem, the lead wire is fusion bonded (sealed) with the aforementioned similar low-melting-point glass. The stem and the cap are mounted by resistance welding to be hermetically sealed.

In the semiconductor laser apparatus disclosed in Japanese Patent Laying-Open No. 2004-22918, however, the package is hermetically sealed with the low-melting-point glass or by resistance welding as described above, and hence a manufacturing process is complicated and the manufacturing cost is disadvantageously increased. Further, a portion hermetically sealed with the low-melting-point glass is not resistant to external shock or the like, and hence the reliability is disadvantageously low.

### SUMMARY OF THE INVENTION

A semiconductor laser apparatus according to a first aspect of the present invention includes a package having sealed space inside, and a semiconductor laser chip arranged in the sealed space, wherein the package has a first member and a second member bonded to each other with an adhesive, a covering agent made of an ethylene-vinyl alcohol copolymer is formed on a bonded region of the first member and the second member in the sealed space, and the adhesive is covered with the covering agent.

In the semiconductor laser apparatus according to the first aspect of the present invention, the first member and the second member constituting the package are bonded to each other with the adhesive, and hence a manufacturing process can be simplified, and the semiconductor laser apparatus can be manufactured at a lower cost. Further, as compared with a case where the first member and the second member are bonded to each other with low-melting-point glass or the like, the adhesive has high flexibility, and hence the adhesive is rarely influenced by external force.

Further, the adhesive is covered with the covering agent in the sealed space, and hence even if the adhesive contains low molecular siloxane or a volatile resin component, the low molecular siloxane or the volatile resin component can be inhibited from entering the sealed space. Further, an ethylene-vinyl alcohol copolymer (EVOH) having excellent gas barrier properties and hardly generating volatile gas is employed as the covering agent, and hence the aforementioned gas can be inhibited from entering the sealed space. Consequently, an adherent substance can be inhibited from being formed on a laser emitting facet, and hence the semiconductor laser chip can be easily inhibited from degradation.

In the aforementioned semiconductor laser apparatus according to the first aspect, the covering agent is preferably arranged to be closer to the sealed space than the adhesive in the bonded region. According to this structure, the adhesive is not exposed in the sealed space, and hence even if the adhesive contains low molecular siloxane or a volatile resin component, the covering agent arranged to be closer to the sealed space than the adhesive can inhibit the component contained in the adhesive from directly entering the sealed space.

In the aforementioned semiconductor laser apparatus according to the first aspect, the covering agent preferably has a surface coming into contact with the sealed space, and the adhesive preferably has a surface exposed to an outside of the package. According to this structure, the covering agent covering the adhesive can partially form an inner surface of the sealed space. Further, the first member and the second member can be reliably bonded with the adhesive in not only the bonded region of the first member and the second member but also an outer surface of the package.

In the aforementioned semiconductor laser apparatus according to the first aspect, the covering agent is preferably arranged to come into contact with the adhesive and cover the adhesive. According to this structure, the covering agent can directly inhibit the component contained in the adhesive from entering the sealed space.

In this case, a contact interface between the covering agent and the adhesive is preferably located on substantially the same plane as an outer surface of the package or located to be closer to the sealed space than the outer surface of the package. According to this structure, the covering agent formed on the bonded region of the first member and the second member does not protrude to the outside of the package, and hence the first member and the second member can be more reliably bonded to each other with the adhesive.

In the aforementioned semiconductor laser apparatus according to the first aspect, the covering agent preferably continuously covers the adhesive along the bonded region of the first member and the second member not to expose the adhesive in the sealed space. According to this structure, the covering agent can reliably prevent the adhesive provided along the bonded region from being exposed in the sealed space, and hence the component contained in the adhesive can be reliably prevented from entering the sealed space.

In the aforementioned semiconductor laser apparatus according to the first aspect, resin having larger elasticity than the adhesive is preferably arranged between the adhesive and the covering agent, and the resin is preferably covered with the covering agent. According to this structure, even if cracks or separation is generated in the adhesive due to a difference in thermal expansion coefficient between the first member and the second member or external impact, the resin can enter clearances generated due to the cracks or the separation. Thus, airtightness and reliability are further improved.

In the aforementioned structure having the resin arranged between the adhesive and the covering agent, the resin having larger elasticity than the adhesive is preferably sealed with the adhesive and the covering agent not to be exposed to an inside and an outside of the sealed space in the bonded region. According to this structure, the airtightness of the package can be reliably inhibited from decrease due to resin exposed to the inside and the outside of the sealed space.

In the aforementioned structure having the resin arranged between the adhesive and the covering agent, the resin having larger elasticity than the adhesive is preferably silicon resin. Thus, the aforementioned function of the “resin having larger elasticity than the adhesive” in the present invention can be effectively utilized by employing the silicon resin.

In the aforementioned semiconductor laser apparatus according to the first aspect, the first member and the second member may be made of different materials. In this case, materials can be easily selected on the basis of shapes and functions of these members.

In this case, either the first member or the second member is preferably made of metal while either the second member or the first member is preferably made of glass, and the first member and the second member are preferably bonded to each other with the adhesive and the covering agent in the bonded region. According to this structure, the package can be constituted by strongly bonding the first member and the second member made of the different materials to each other with the adhesive and the covering agent.

In the aforementioned semiconductor laser apparatus according to the first aspect, the first member is preferably transparent and bonded onto an opening of the second member, a laser beam emitted from the semiconductor laser chip is preferably transmitted through the first member and emitted to an outside of the package, and the covering agent is preferably formed on a bonded region of the second member and the first member other than the opening. According to this structure, the package can be easily sealed also in a window portion (bonded region) for emitting a laser beam such that the component contained in the adhesive is inhibited from entering the sealed space.

In this case, the first member is preferably bonded onto a surface of the second member in the sealed space of the package or a surface of the second member on the outside of the package opposite to the sealed space, and the first member and the second member are preferably bonded to each other with the adhesive and the covering agent arranged on a surface of the second member other than the opening. According to this structure, the package can be easily sealed with the first member (window portion) for emitting a laser beam without harmful effects such as contact of the laser beam with the covering agent.

In the aforementioned semiconductor laser apparatus according to the first aspect, the first member preferably has conductivity and is preferably bonded onto an opening of the second member, the first member is preferably arranged to extend from an outside of the package to an inside of the sealed space in a state electrically isolated from the second member, and the covering agent is preferably formed in the opening of the second member. According to this structure, the package can be easily sealed also in a wiring portion for power supply to the semiconductor laser chip arranged in the sealed space and a wiring portion for a monitor signal from a photodiode (photodetector) such that the component contained in the adhesive is inhibited from entering the sealed space.

In this case, the first member is preferably a lead frame, the second member is preferably a base for fixing the semiconductor laser chip in the sealed space, the lead frame preferably extends from the outside of the package to the inside of the sealed space in a state held in an opening of the base by the adhesive sealing the opening of the base, and a surface of the adhesive in a portion on which the lead frame is mounted is preferably covered with the covering agent in the sealed space. According to this structure, the package can be easily sealed in the wiring portion for power supply to the semiconductor laser chip arranged in the sealed space and the wiring portion for a monitor signal from the photodiode (photodetector).

In the aforementioned semiconductor laser apparatus according to the first aspect, the first member is preferably a sealing member sealing the package, the second member is preferably a base for fixing the semiconductor laser chip in the sealed space, the sealing member and the base are preferably bonded to each other with the adhesive, and the covering agent covering the adhesive preferably extends onto a surface of the sealing member other than the bonded region on a side bonded to the base. According to this structure, the covering agent can be easily formed on one surface (inner surface) of the sealing member in the manufacturing process. Further, the surface of the sealing member located in the sealed space can be reliably covered with the covering agent regardless of a bonding position (mounting method) of the sealing member to the base.

The aforementioned semiconductor laser apparatus according to the first aspect preferably further includes a photodetector arranged in the sealed space, monitoring intensity of a laser beam from the semiconductor laser chip, wherein the photodetector is fixed in the sealed space through a conductive adhesive containing a volatile component, and a surface of the conductive adhesive fixing the photodetector exposed in the sealed space is covered with the covering agent. According to this structure, the covering agent can block volatile organic gas from penetrating into the sealed space of the package even if the volatile organic gas is generated from the conductive adhesive. Consequently, formation of an adherent substance on a photodetecting surface of the photodetector in addition to the laser emitting facet can be inhibited, and hence output of a laser beam from the semiconductor laser chip can be accurately controlled with this photodetector

In the aforementioned semiconductor laser apparatus according to the first aspect, the adhesive is preferably made of a resin material containing a volatile component. Thus, even if the resin material containing the volatile component is employed as the adhesive, the “covering agent” in the present invention covers the adhesive, and hence the effects of the present invention can be effectively achieved.

In the aforementioned semiconductor laser apparatus according to the first aspect, the semiconductor laser chip preferably includes a nitride-based semiconductor laser chip. Thus, in the nitride-based semiconductor laser chip having a short lasing wavelength and requiring a higher output power, an adherent substance is easily formed on a laser emitting facet thereof, and hence the use of the aforementioned “covering agent” in the present invention is highly effective in inhibiting degradation of the nitride-based semiconductor laser chip.

An optical apparatus according to a second aspect of the present invention includes a semiconductor laser apparatus including a package having sealed space inside and a semiconductor laser chip arranged in the sealed space, and an optical system controlling a beam emitted from the semiconductor laser chip, wherein the package has a first member and a second member bonded to each other with an adhesive, a covering agent made of an ethylene-vinyl alcohol copolymer is formed on a bonded region of the first member and the second member in the sealed space, and the adhesive is covered with the covering agent.

In the optical apparatus according to the second aspect of the present invention, the first member and the second member in the sealed space are bonded to each other with the adhesive, and hence a manufacturing process can be simplified, and the semiconductor laser apparatus can be manufactured at a lower cost. Further, as compared with a case where the first member and the second member are bonded to each other with low-melting-point glass or the like, the adhesive has high flexibility, and hence the adhesive is rarely influenced by external force.

Further, the adhesive is covered with the covering agent, and hence even if the adhesive contains low molecular siloxane or a volatile resin component, the low molecular siloxane or the volatile resin component can be inhibited from entering the sealed space. Further, an ethylene-vinyl alcohol copolymer (EVOH) having excellent gas barrier properties and hardly generating volatile gas is employed as the covering agent, and hence the aforementioned gas can be inhibited from entering the sealed space. Consequently, an adherent substance can be inhibited from being formed on a laser emitting facet, and hence the semiconductor laser chip can be easily inhibited from degradation. Thus, the reliable optical apparatus can be easily attained at a lower cost.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is an exploded perspective view of a semiconductor laser apparatus 100 in which a base 10 and a sealing member 20 are separated from each other;

FIG. 2 is a longitudinal sectional view taken along the center line of the semiconductor laser apparatus 100 in the width direction;

FIG. 3 is a longitudinal sectional view of the vicinity of a through hole 11c (11d) in the semiconductor laser apparatus 100;

FIG. 4 is a longitudinal sectional view taken along the center line of a semiconductor laser apparatus 110 in the width direction;

FIG. 5 is an exploded perspective view of a semiconductor laser apparatus 200 in which a base 10 and a sealing member 20 are separated from each other;

FIG. 6 is a longitudinal sectional view taken along the center line of the semiconductor laser apparatus 200 in the width direction;

FIG. 7 is a partial sectional view of a terminal holding portion 55 through which a lead frame 14 (15) of the semiconductor laser apparatus 200 passes;

FIG. 8 is an exploded perspective view of a semiconductor laser apparatus 210 in which a base 10 and a sealing member 20 are separated from each other;

FIG. 9 is an exploded perspective view of a semiconductor laser apparatus 220 in which a base 10 and a sealing member 20 are separated from each other;

FIG. 10 is a longitudinal sectional view taken along the center line of the semiconductor laser apparatus 220 in the width direction;

FIG. 11 is a longitudinal sectional view of the vicinity of a through hole 11c (11d) in the semiconductor laser apparatus 220; and

FIG. 12 is a schematic diagram showing the structure of an optical pickup 300 including the semiconductor laser apparatus 210.

### DESCRIPTION OF THE PREFERRED EMBODIMENTS

Embodiments of the present invention are hereinafter described with reference to the drawings.

### First Embodiment

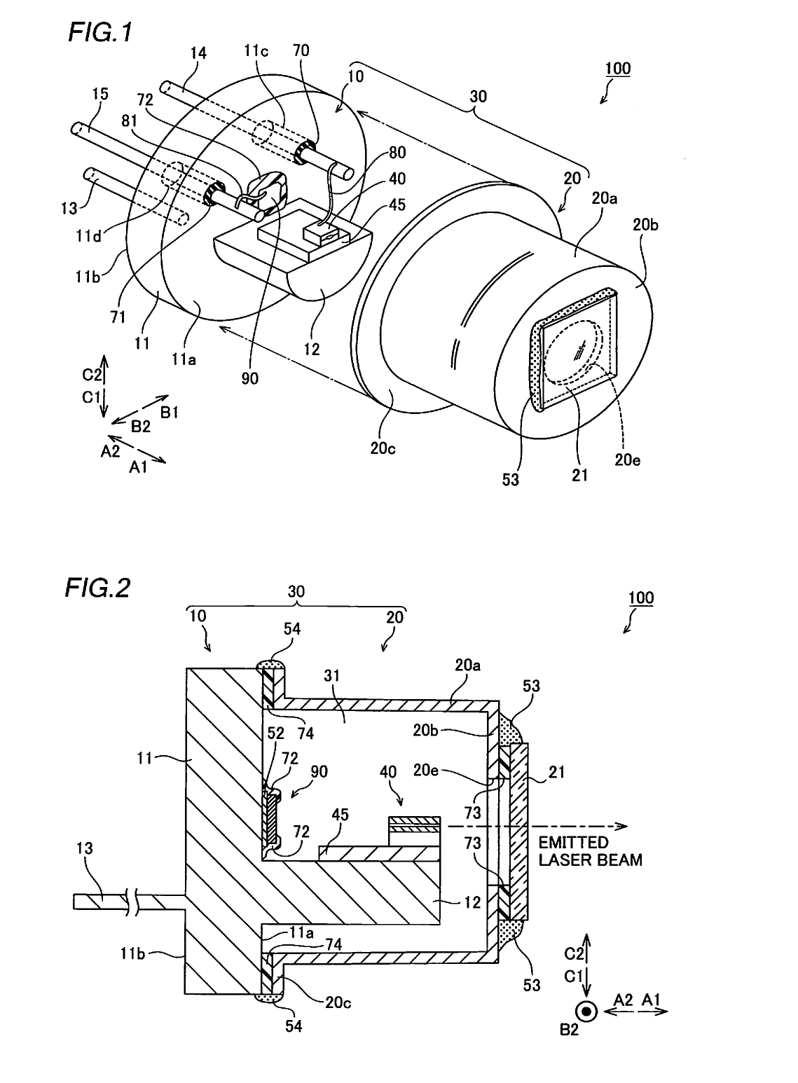

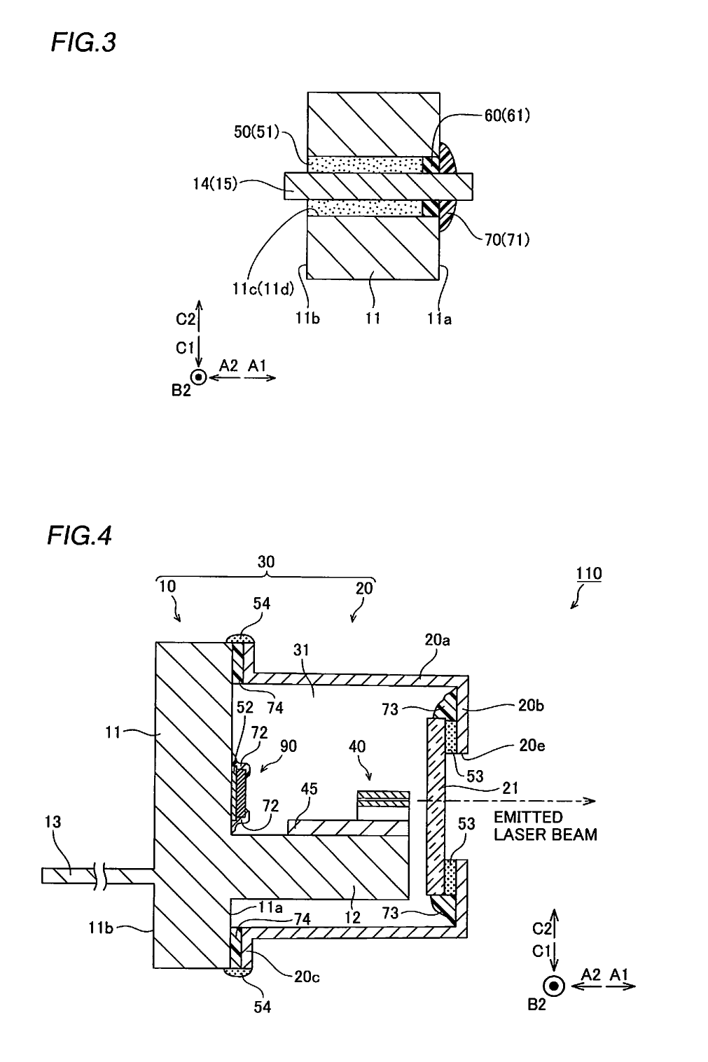

A semiconductor laser apparatus 100 according to a first embodiment of the present invention is now described. As shown in FIGS. 1 to 3, this semiconductor laser apparatus 100 includes a package 30 having a base 10 and a sealing member 20, and a blue-violet semiconductor laser chip 40 having a lasing wavelength of about 405 nm is sealed in the package. The blue-violet semiconductor laser chip 40 is an example of the “semiconductor laser chip” in the present invention.

The base 10 is made of kovar, which is a Fe—Ni—Co alloy with a Ni—Au plated surface, and has a disc-shaped stem 11 and a protruding block 12 protruding forward from a front surface 11a of the stem 11.

Lead frames 13, 14 and 15 extending backward (in a direction A2) are provided on a rear surface 11b of the stem 11. The lead frame 13 is formed integrally with the base 10 and electrically connected with the base 10. Through holes 11c and 11d are formed on the same plane parallel to an upper surface (surface on a C2 side) of the protruding block 12 in the stem 11. The lead frames 14 and 15 pass through the through holes 11c and 11d and extend to the front (on an A1 side) of the stem 11. The lead frames 14 and 15 are bonded with adhesives 50 and 51 made of epoxy resin filled into the through holes 11c and 11d in a state electrically insulated from the base 10. The through holes 11c and 11d are examples of the “opening” in the present invention.

Silicon resins 60 and 61 are filled into front portions of the through holes 11c and 11d not to expose the adhesives 50 and 51 on the front side. The silicon resins 60 and 61 are examples of the “resin having larger elasticity than the adhesive” in the present invention. Covering agents 70 and 71 each made of an ethylene-polyvinyl alcohol copolymer (EVOH resin) are formed on openings of the through holes 11c and 11d in the front surface 11a not to expose the silicon resins 60 and 61. In other words, contact interfaces between the silicon resins 60 and 61 and the adhesives 50 and 51 are not exposed to the outside of the package 30. Contact interfaces between the silicon resins 60 and 61 and the covering agents 70 and 71 are also not exposed to sealed space 31. In this case, the covering agents 70 and 71 have surfaces coming into contact with the sealed space 31. The adhesives 50 and 51 are exposed to the outside of the package 30. A film of EVOH resin is arranged to cover the silicon resins 60 and 61, and thereafter melted by heat of about 200° C., whereby the covering agents 70 and 71 are formed.

The blue-violet semiconductor laser chip 40 is bonded onto the upper surface of the protruding block 12 through a submount 45. The blue-violet semiconductor laser chip 40 is arranged such that in a pair of cavity facets of the blue-violet semiconductor laser chip 40, that (light-emitting surface) emitting a laser beam having relatively large light intensity faces frontward (in a direction A1) and that (light-reflecting surface) emitting a laser beam having relatively small light intensity faces backward (in the direction A2).

An n-side electrode (not shown) formed on a lower surface (surface on a C1 side) of the blue-violet semiconductor laser chip 40 is electrically connected with the protruding block 12 and the lead frame 13 through the submount 45. A p-side electrode (not shown) formed on an upper surface (surface on the C2 side) of the blue-violet semiconductor laser chip 40 is electrically connected with a front end of the lead frame 14 through a metal wire 80 made of Au or the like.

A photodiode (PD) 90 is mounted on the front surface 11a of the stem 11. The photodiode (PD) 90 is an example of the “photodetector” in the present invention. The PD 90 is arranged such that a front surface (photodetecting surface) thereof is opposed to the light-reflecting surface of the blue-violet semiconductor laser chip 40. An n-side electrode (not shown) formed on a rear surface of the PD 90 is electrically connected with the stem 11 and the lead frame 13 through a conductive adhesive 52 containing a volatile component or the like. A p-side electrode (not shown) formed on the front surface of the PD 90 is electrically connected with a front end of the lead frame 15 through a metal wire 81 made of Au or the like. A covering agent 72 made of EVOH resin is formed between a side surface of the PD 90 and the front surface 11a of the stem 11 to cover the conductive adhesive 52. Similarly to the covering agent 71, a film of EVOH resin is arranged around the PD 90, and thereafter melted by heat of about 200° C., whereby the covering agent 72 is formed.

The sealing member 20 is made of kovar with a Ni-plated surface and formed in the form of a cap, which opens on the rear side. The sealing member 20 has a side wall portion 20a cylindrically formed, a bottom portion 20b closing the front side of the side wall portion 20a, and a mounting portion 20c formed on the rear side of the side wall portion 20 and jutting out toward the outer periphery similarly to the outer shape of the stem 11.

A circular hole 20e is provided in a center of the bottom portion 20b of the sealing member 20, and a rectangular light transmission portion 21 made of borosilicate glass is bonded to cover the hole 20e from the front side. The hole 20e is an example of the “opening” in the present invention. A covering agent 73 made of EVOH resin is formed between a rear surface of the light transmission portion 21 and a front surface of the bottom portion 20b excluding the hole 20e. A clearance between the light transmission portion 21 and the bottom portion 20b is filled up with the covering agent 73 to be sealed, and the covering agent 73 has a surface (annular inner surface) coming into contact with the sealed space 31. A film of EVOH resin having an opening with a shape substantially identical to that of the hole 20e is held between the light transmission portion 21 and the bottom portion 20e, and thereafter melted by heat of about 200° C., whereby the covering agent 73 can be formed. An adhesive 53 made of epoxy resin is formed between a side surface of the light transmission portion 21 and the bottom portion 20b of the sealing member 20, and the light transmission portion 21 and the bottom portion 20b are fixed with this adhesive 53. Thus, a surface of the adhesive 53 partially forms an outer surface of the package 30. The adhesive 53 can be formed by being applied onto the periphery of the light transmission portion 21 after the covering agent 73 is formed. The covering agent 73 comes into contact with the adhesive 53 and covers the adhesive 53. A contact interface between the covering agent 73 and the adhesive 53 is located in the vicinity of a boundary between a bonded region of the sealing member 20 and the light transmission portion 21 and the outer surface of the package.

The base 10 and the sealing member 20 are sealed with a covering agent 74 made of EVOH resin formed between the front surface 11a of the stem 11 and the mounting portion 20c of the sealing member 20, and the covering agent 74 has a surface (annular inner surface) coming into contact with the sealed space 31. A film of EVOH resin having a substantially identical shape to the mounting portion 20c is held between the front surface 11a and the mounting portion 20c, and thereafter melted by heat of about 200° C., whereby the covering agent 74 can be formed. An adhesive 54 made of epoxy resin is formed between a side surface of the mounting portion 20c and a side surface of the stem 11, and the mounting portion 20c and the stem 11 are fixed with this adhesive 54. Thus, a surface of the adhesive 54 partially forms the outer surface of the package 30. The adhesive 54 can be formed by being applied onto a region between the side surface of the mounting portion 20c and the side surface of the stem 11 after the covering agent 74 is formed. The covering agent 74 comes into contact with the adhesive 54 and covers the adhesive 54. A contact interface between the covering agent 74 and the adhesive 54 is located in the vicinity of a boundary between a bonded region of the base 10 and the sealing member 20 and the outer surface of the package. Thus, the semiconductor laser apparatus 100 having the blue-violet semiconductor laser chip 40 sealed in the sealed space 31 of the package 30 surrounded by the base 10 and the sealing member 20 is formed.

In the relation between the base 10 and the sealing member 20 of the semiconductor laser apparatus 100, either the base 10 or the sealing member 20 is an example of the “first member” in the present invention, and either the sealing member 20 or the base 10 is an example of the “second member” in the present invention. In the relation between the base 10 and the lead frames 14 and 15, the lead frames 14 and 15 are examples of the “first member” in the present invention, and the base 10 is an example of the “second member” in the present invention. In the relation between the sealing member 20 and the light transmission portion 21, the light transmission portion 21 is an example of the “first member” in the present invention, and the sealing member 20 is an example of the “second member” in the present invention.

In the semiconductor laser apparatus 100, the base 10, the sealing member 20, the light transmission portion 21 and the lead frames 14 and 15 constituting the package are bonded with the adhesives 50, 51, 53 and 54, and hence a manufacturing process for the semiconductor laser apparatus 100 can be simplified, and the semiconductor laser apparatus 100 can be manufactured at a lower cost. Further, the members can be strongly bonded to each other. As compared with a case where the members are bonded to each other with low-melting-point glass or the like, the adhesives have high flexibility, and hence the adhesives are rarely influenced by external force. Further, the adhesives 50, 51, 53 and 54 are covered with the covering agent 70, 71, 73 and 74 in the sealed space 31, and hence even if the adhesives 50, 51, 53 and 54 contain low molecular siloxane or volatile resin components, the low molecular siloxane or the volatile resin components can be inhibited from entering the sealed space 31. Further, EVOH having excellent gas barrier properties and hardly generating volatile gas is employed as the covering agents 70, 71, 73 and 74, and hence the aforementioned gas can be inhibited from entering the sealed space 31. Consequently, an adherent substance can be inhibited from being formed on a light-emitting surface of the blue-violet semiconductor laser chip 40, and hence the blue-violet semiconductor laser chip 40 can be easily inhibited from degradation. Especially in the blue-violet semiconductor laser chip 40 having a short lasing wavelength and requiring a higher output power, an adherent substance is easily formed on a laser emitting facet thereof, and hence it is highly effective to cover the adhesives 50, 51, 53 and 54 with the covering agents 70, 71, 73 and 74.

In the semiconductor laser apparatus 100, the covering agents 70, 71, 73 and 74 are arranged to be closer to the sealed space 31 than the adhesives 50, 51, 53 and 54 in bonded regions between the members, and hence the adhesives 50, 51, 53 and 54 are not exposed in the sealed space 31. Therefore, even if the adhesives 50, 51, 53 and 54 contain low molecular siloxane or volatile resin components, the covering agents 70, 71, 73 and 74 arranged to be closer to the sealed space 31 than the aforementioned adhesives can inhibit the components contained in the adhesives 50, 51, 53 and 54 from directly entering the sealed space 31.

In the semiconductor laser apparatus 100, the covering agents 70, 71, 73 and 74 have the surfaces coming into contact with the sealed space 31, and the adhesives 50, 51, 53 and 54 have surfaces exposed to the outside of the package 30. Thus, the covering agents 70, 71, 73 and 74 covering the adhesives 50, 51, 53 and 54, respectively, can partially form an inner surface of the sealed space 31. Further, the base 10, the sealing member 20 and the light transmission portion 21 can be reliably bonded with the adhesives 50, 51, 53 and 54 in not only the bonded regions between the base 10, the sealing member 20 and the light transmission portion 21 but also the outer surface of the package 30.

In the semiconductor laser apparatus 100, the covering agents 73 and 74 are arranged to come into contact with the adhesives 53 and 54 and cover the adhesives 53 and 54, respectively. Thus, the covering agents 73 and 74 can directly inhibit the components contained in the adhesives 53 and 54 from entering the sealed space 31.

In the semiconductor laser apparatus 100, the contact interfaces between the covering agents 73 and 74 and the adhesives 53 and 54, respectively, are located in the vicinity of the outer surface of the package 30 or on substantially the same plane, and hence the covering agents 73 and 74 formed on the bonded regions between the base 10, the sealing member 20 and the light transmission portion 21 do not protrude to the outside of the package 30. Therefore, the base 10, the sealing member 20 and the light transmission portion 21 can be more reliably bonded with the adhesives 53 and 54 in the substantially flat outer surface of the package 30.

In the semiconductor laser apparatus 100, the covering agents 70, 71, 73 and 74 continuously cover the adhesives 50, 51, 53 and 54 along the bonded regions between the base 10, the lead frames 14 and 15, the sealing member 20 and the light transmission portion 21 not to expose the adhesives 50, 51, 53 and 54 in the sealed space 31. Thus, the aforementioned covering agents can reliably prevent the adhesives provided along the bonded regions from being exposed in the sealed space 31, and hence the components contained in the adhesives 50, 51, 53 and 54 can be reliably prevented from entering the sealed space 31.

The semiconductor laser apparatus 100 is formed as described above, and hence materials for the base 10, the lead frames 14 and 15, the sealing member 20 and the light transmission portion 21 can be easily selected on the basis of shapes and functions of these members.

The semiconductor laser apparatus 100 is formed as described above, and hence the package can be easily sealed also in the light transmission portion 21 (window portion) for emitting a laser beam such that the component contained in the adhesive 53 is inhibited from entering the sealed space 31.

In the semiconductor laser apparatus 100, the light transmission portion 21 is bonded onto an outer surface of the bottom portion 20b of the sealing member 20 constituting the package, and the light transmission portion 21 and the sealing member 20 are bonded to each other with the adhesive 53 and the covering agent 73 arranged on a surface of the sealing member 20 other than the hole 20e. Thus, the package can be easily sealed with the light transmission portion 21 (window portion) for emitting a laser beam without harmful effects such as contact of the laser beam with the covering agent 73.

The semiconductor laser apparatus 100 is formed as described above, and hence the package can be easily sealed also in a wiring portion (through hole 11c) for power supply to the semiconductor laser chip 40 and a wiring portion (through hole 11d) for a monitor signal from the PD 90 such that the components contained in the adhesives 50 and 51 are inhibited from entering the sealed space 31.

In the bonded regions of the lead frames 14 and 15 and the stem 11, the silicon resins 60 and 61 are arranged between the adhesives 50 and 51 and the covering agents 70 and 71, respectively. Thus, even if cracks or separation is generated in the adhesives 50 and 51 due to external impact or a difference in thermal expansion coefficient between the lead frames 14 and 15 and the stem 11, the silicon resins 60 and 61 can enter clearances generated due to the cracks or the separation, and hence airtightness and reliability are further improved.

In the semiconductor laser apparatus 100, the covering agent 72 made of EVOH is formed in the periphery of the PD 90 to cover the conductive adhesive 52 fixing the PD 90. Thus, even if the conductive adhesive 52 contains low molecular siloxane or a volatile resin component, the low molecular siloxane or the volatile resin component can be inhibited from entering the sealed space 31. Consequently, an adherent substance can be inhibited from being formed on the photodetecting surface of the photodetector in addition to the laser emitting facet, and hence output of a laser beam from the semiconductor laser chip can be accurately controlled with this photodetector.

In the semiconductor laser apparatus 100, the covering agents 70, 71, 73 and 74 cover the adhesives 50, 51, 53 and 54 made of epoxy resin containing a volatile component, respectively, and hence the effects of the present invention can be effectively achieved.

### Modification of First Embodiment

A semiconductor laser apparatus 110 according to a modification of the first embodiment is now described. In this semiconductor laser apparatus 110, a light transmission portion 21 is mounted on the inside of a bottom portion 20b of a sealing member 20, as shown in FIG. 4. In this case, an adhesive 53 fixing the light transmission portion 21 and the bottom portion 20b to each other is formed between a front surface of the light transmission portion 21 and an inner surface of the bottom portion 20b excluding a hole 20e. A covering agent 73 covering the adhesive 53 is formed between a side surface of the light transmission portion 21 and the inner surface of the bottom portion 20b on the inside of the sealing member 20 and arranged not to expose the adhesive 53 to the inside of the sealing member 20. The remaining structure is similar to that of the semiconductor laser apparatus 100.

The semiconductor laser apparatus 110 also achieves effects similar to those of the semiconductor laser apparatus 100.

### Second Embodiment

A semiconductor laser apparatus 200 according to a second embodiment of the present invention is now described.

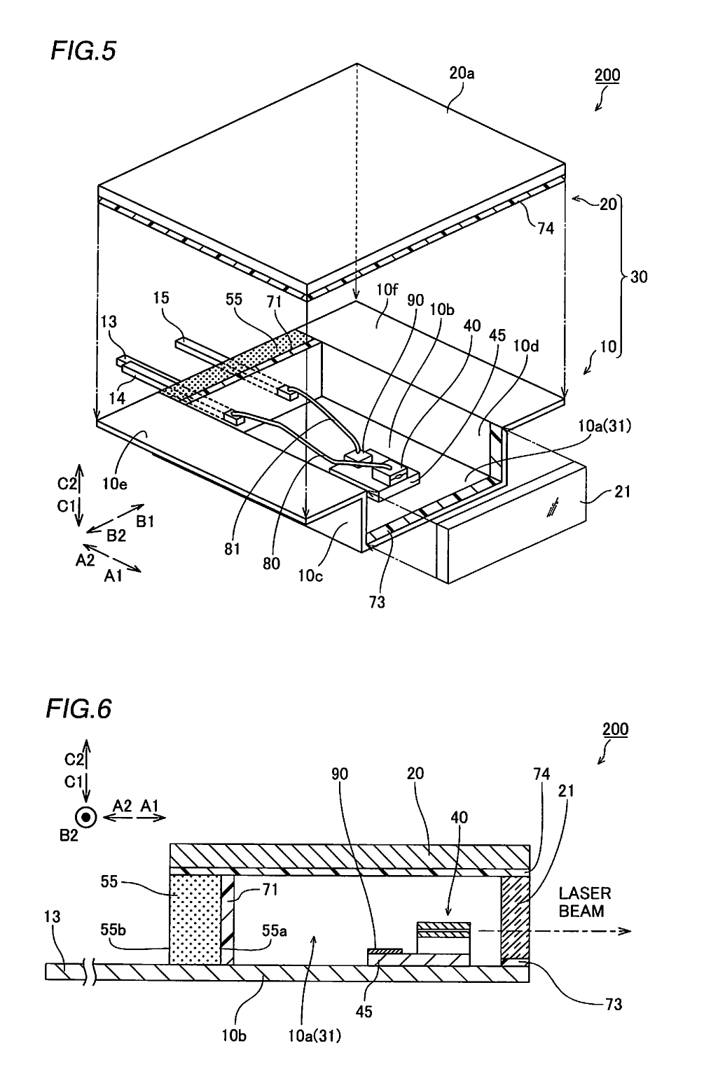

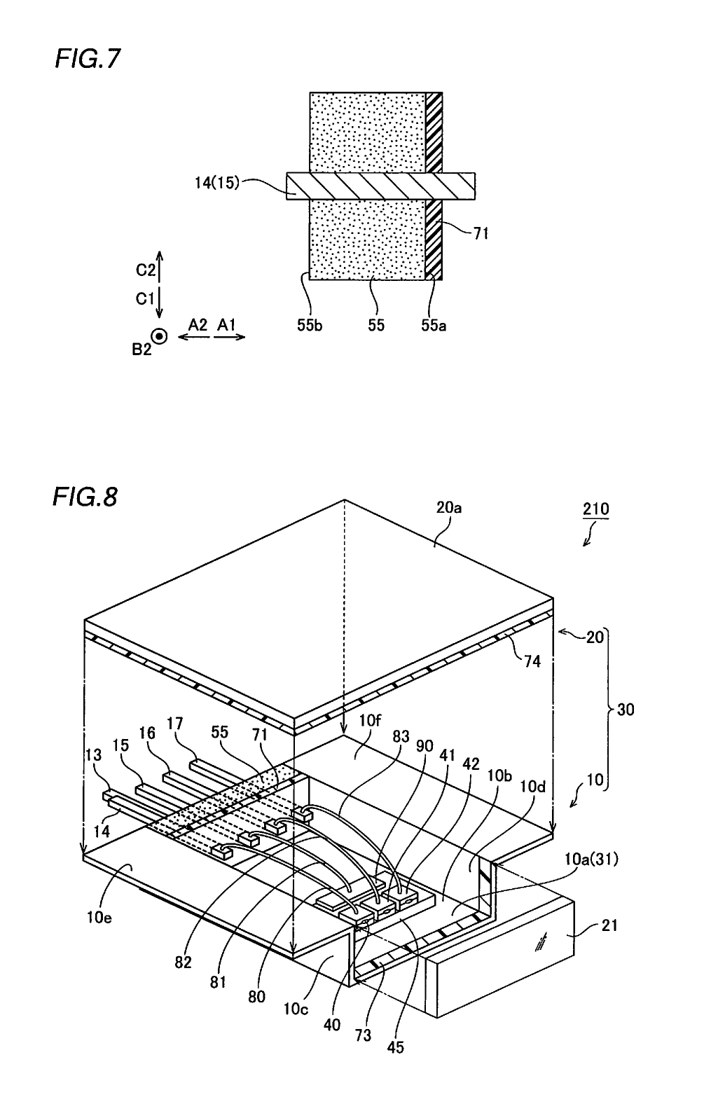

As shown in FIGS. 5 to 7, a base 10 of this semiconductor laser apparatus 200 is made of a frame-shaped metal plate of phosphor bronze having a thickness of about 0.4 mm with a Ni-plated surface. A groove-shaped recess portion 10a, which opens on the front side (in a direction A1), the rear side (in a direction A2) and the upper side (in a direction C2), is formed by bending in the base 10. Regions, which open on the front side and the rear side of the recess portion 10a, are examples of the “opening” in the present invention. A lead frame 13 extending backward is integrally formed on a bottom surface 10b of the base 10. Side surfaces 10c and 10d of the recess portion 10a have the same height, and mounting portions 10e and 10f extending parallel to the bottom surface 10b are formed above the side surfaces 10c and 10d.

A light transmission portion 21 made of borosilicate glass with a shape identical to that of the cross section of the recess portion 10a is fitted into a front portion of the recess portion 10a. A covering agent 73 made of EVOH resin with a thickness of about 0.5 mm is formed between the light transmission portion 21 and the bottom surface 10b and the side surfaces 10c and 10d of the recess portion 10a. A clearance between the light transmission portion 21 and the recess portion 10a is filled up with the covering agent 73 to seal a package, and the light transmission portion 21 is bonded with the covering agent 73 in the recess portion 21.

A terminal holding portion 55 made of epoxy resin with a shape identical to that of the cross section of the recess portion 10a is formed on a rear portion of the base 10. The terminal holding portion 55 is an example of the “adhesive” in the present invention. A covering agent 71 made of EVOH resin is formed on a front surface 55a (surface inside the recess portion 10a) of the terminal holding portion 55. The covering agent 71 covers the front surface 55a not to expose the terminal holding portion 55 as viewed from the inside of the recess portion 10a. Lead frames 14 and 15 pass through the terminal holding portion 55 and the covering agent 71 on the same plane parallel to the bottom surface 10b of the recess portion 10a and extend to the inside of the recess portion 10a. The lead frames 14 and 15 are held in a state electrically insulated from each other by the terminal holding portion 55. The terminal holding portion 55 is formed by pouring epoxy resin into the rear portion of the recess portion 10a while holding the lead frames 14 and 15 at prescribed positions. The covering agent 71 is formed by applying EVOH resin onto the front surface 55a of the terminal holding portion 55 in a state where the base 10 is heated to about 220° C. after the terminal holding portion 55 is formed.

A blue-violet semiconductor laser chip 40 is bonded onto the bottom surface 10b of the recess portion 10a through a submount 45. The blue-violet semiconductor laser chip 40 is arranged on a front portion of an upper surface of the submount 45, and a PD 90 is bonded onto a rear portion of the upper surface of the submount 45 such that a photodetecting surface (not shown) faces upward.

A sealing member 20 is made of a metal plate 20a of nickel silver with a thickness of about 15 μm and has a shape similar to the planar shape of the base 10. A covering agent 74 made of EVOH resin with a thickness of about 0.5 mm is formed on a lower surface of the sealing member 20, and the sealing member 20 is bonded onto upper surfaces of the mounting portions 10e and 10f of the base 10, the terminal holding portion 55 and the light transmission portion 21 through the covering agent 74.

Thus, the semiconductor laser apparatus 200 having the blue-violet semiconductor laser chip 40 sealed in sealed space 31 of the package 30 surrounded by the base 10, the terminal holding portion 55, the light transmission portion 21 and the sealing member 20 is formed. The remaining structure of the semiconductor laser apparatus 200 is similar to that of the semiconductor laser apparatus 100.

In the relation between the sealing member 20 and the base 10, the lead frames 14 and 15 and the light transmission portion 21 of the semiconductor laser apparatus 200, either the sealing member 20 or the base 10, the lead frames 14 and 15 and the light transmission portion 21 are examples of the “first member” in the present invention, and either the base 10, the lead frames 14 and 15 and the light transmission portion 21 or the sealing member 20 is an example of the “second member” in the present invention. In the relation between the base 10 and the lead frames 14 and 15, the lead frames 14 and 15 are examples of the “first member” in the present invention, and the base 10 is an example of the “second member” in the present invention. In the relation between the base 10 and the light transmission portion 21, the light transmission portion 21 is an example of the “first member” in the present invention, and the base 10 is an example of the “second member” in the present invention.

In the semiconductor laser apparatus 200, the base 10 and the sealing member 20 each are made of a metal plate, and hence the semiconductor laser apparatus 200 can be manufactured at a lower cost. Further, the light transmission portion 21 and the sealing member 20 are bonded with the covering agents 73 and 74, respectively. In other words, no adhesive is employed in those bonded regions, and hence a volatile resin component contained in an adhesive hardly enters the sealed space 31. Further, the semiconductor laser apparatus 200 can be manufactured at a lower cost.

The remaining effects of the semiconductor laser apparatus 200 are similar to those of the semiconductor laser apparatus 100.

### First Modification of Second Embodiment

A semiconductor laser apparatus 210 according to a first modification of a second embodiment is now described. In this semiconductor laser apparatus 210, a blue-violet semiconductor laser chip 40 having a lasing wavelength of about 405 nm, a red semiconductor laser chip 41 having a lasing wavelength of about 650 nm and an infrared semiconductor laser chip 42 having a lasing wavelength of about 780 nm are aligned on a submount 45 and bonded thereto, as shown in FIG. 8. Laser beams are emitted parallel to an anterior direction (direction A1) from these semiconductor laser chips. The blue-violet semiconductor laser chip 40, the red semiconductor laser chip 41 and the infrared semiconductor laser chip 42 are examples of the “semiconductor laser chip” in the present invention.

In the semiconductor laser apparatus 210, four lead frames 14, 15, 16 and 17 pass through a terminal holding portion 55 and a covering agent 71 on the same plane parallel to a bottom surface 10b of a recess portion 10a are arranged in this order in the width direction (direction B1). The lead frame 14 is connected with the blue-violet semiconductor laser chip 40 through a metal wire 80, the lead frame 15 is connected with a PD 90 through a metal wire 81, the lead frame 16 is connected with the red semiconductor laser chip 41 through a metal wire 82 and the lead frame 17 is connected with the infrared semiconductor laser chip 42 through a metal wire 83. The remaining structure is similar to that of the semiconductor laser apparatus 200.

In the semiconductor laser apparatus 210, laser beams of three different wavelengths can be emitted. The remaining effects of the semiconductor laser apparatus 210 are similar to those of the semiconductor laser apparatus 200.

### Second Modification of Second Embodiment

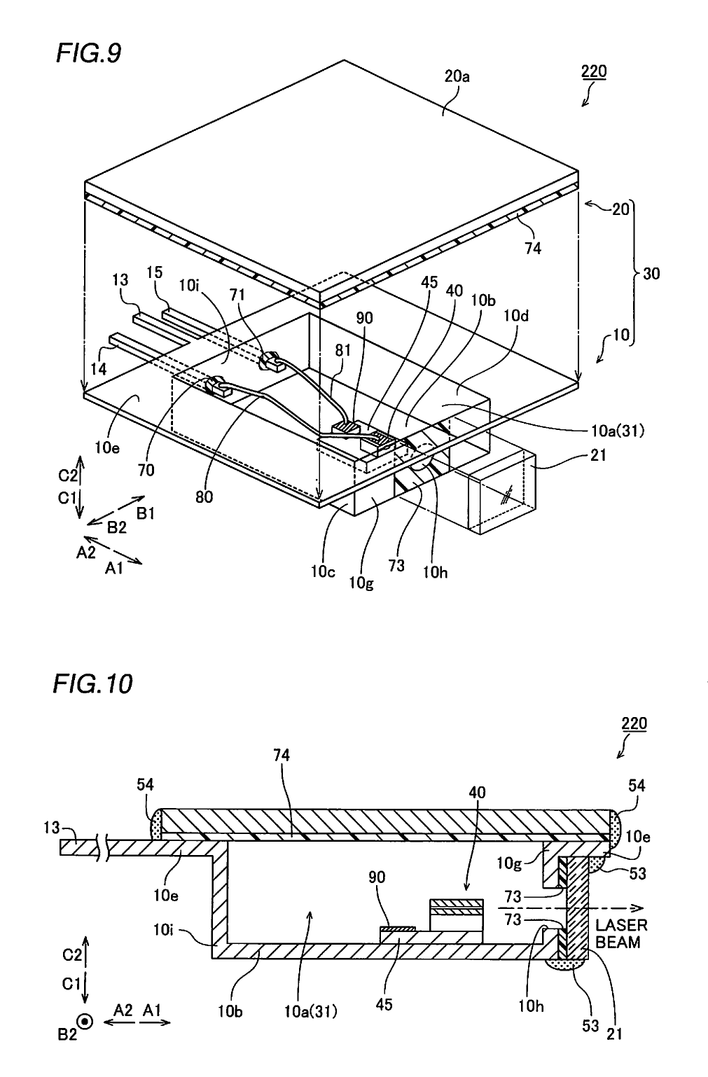

A semiconductor laser apparatus 220 according to a second modification-of a second embodiment is now described. A base 10 of this semiconductor laser apparatus 220 includes a box-shaped recess portion 10a formed with a front surface 10g and a rear surface 10i on the front side (in a direction A1) and the rear side (in a direction A2), respectively in place of the groove-shaped recess portion 10a of the semiconductor laser apparatus 200, as shown in FIGS. 9 and 10. The recess portion 10a is formed by pressing a metal plate.

A circular hole 10h is provided in the center of the front surface 10g of the recess portion 10a, and a rectangular light transmission portion 21 is provided to cover the hole 10h from the front side. Methods of fixing and sealing the light transmission portion 21 are similar to those of the light transmission portion 21 of the semiconductor laser apparatus 100.

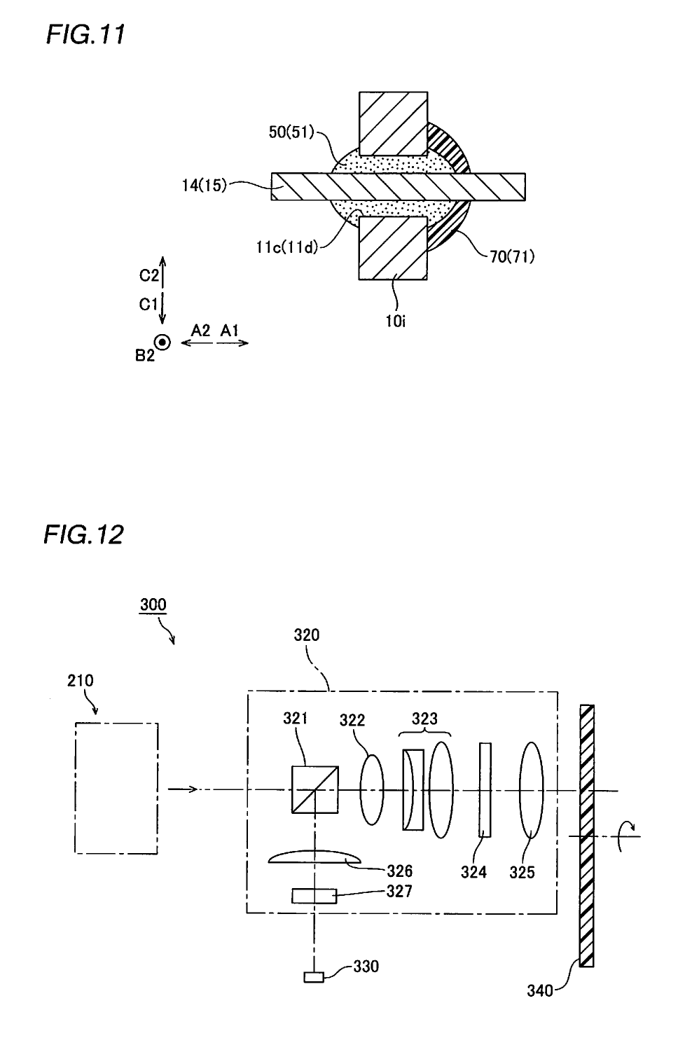

As shown in FIG. 11, through holes 11c and 11d are formed on the same plane parallel to a bottom surface 10b of the recess portion 10a in the rear surface 10i of the recess portion 10a. Lead frames 14 and 15 pass through the through holes 11c and 11d and extend to the inside of the recess portion 10a. The lead frames 14 and 15 are held in a state electrically insulated from each other by adhesives 50 and 51 made of epoxy resin filled into the through holes 11c and 11d. Covering agents 70 and 71 made of EVOH resin are formed in openings of the through holes 11c and 11d inside the recess portion 10a to cover the adhesives 50 and 51. The hole 10h and the through holes 11c and 11d are examples of the “opening” in the present invention.

A mounting portion 10e of an upper surface of the base 10 is formed in a frame shape surrounding the recess portion 10a, and a lead frame 13 is integrally formed on a rear portion of the mounting portion 10e. A sealing member 20 is bonded onto an upper surface of the mounting portion 10e through a covering agent 74. An adhesive 54 made of epoxy resin is formed on a side surface of the sealing member 20 and a side surface of the mounting portion 10e of the base 10, whereby the sealing member 20 and the base 10 are bonded to each other. The remaining structure of the semiconductor laser apparatus 220 is similar to that of the semiconductor laser apparatus 200.

In the relation between the base 10 and the sealing member 20 of the semiconductor laser apparatus 220, either the base 10 or the sealing member 20 is an example of the “first member” in the present invention, and either the sealing member 20 or the base 10 is an example of the “second member” in the present invention. In the relation between the lead frames 14 and 15 and the light transmission portion 21 and the base 10, the lead frames 14 and 15 and the light transmission portion 21 are examples of the “first member” in the present invention, and the base 10 is an example of the “second member” in the present invention.

In the semiconductor laser apparatus 220, the light transmission portion 21 and the sealing member 20 are bonded to the base 10 with adhesives 53 and 54, and hence the light transmission portion 21 and the sealing member 20 are more strongly fixed and the reliability is high. Further, the aforementioned adhesives 53 and 54 are covered with covering agents 73 and 74 as viewed from the inside of sealed space 31, and hence even if the adhesives 53 and 54 contain low molecular siloxane or a volatile resin component, the low molecular siloxane or the volatile resin component can be inhibited from entering the sealed space 31.

In the semiconductor laser apparatus 220, contact interfaces between the covering agents 70 and 71 and the adhesives 50 and 51, respectively, extend out from bonded regions of the base 10 and the lead frames 14 and 15 toward the sealed space 31, and hence the covering agents 70 and 71 do not protrude toward the bonded regions of the base 10 and the lead frames 14 and 15. Therefore, the base 10 and the lead frames 14 and 15 can be reliably bonded with the adhesives 50 and 51 by sufficiently utilizing the bonded regions of the base 10 and the lead frames 14 and 15.

In the semiconductor laser apparatus 220, the sealing member 20 and the base 10 are bonded to each other with the adhesive 54, and the covering agent 74 covering the adhesive 54 extends onto an inner surface (back surface) of the sealing member 20 other than a bonded region bonded to the base 10. Thus, the covering agent 74 can be easily formed on one surface (inner surface) of the sealing member 20 in a manufacturing process. Further, the inner surface of the sealing member 20 can be reliably covered with the covering agent 74 regardless of a bonding position (mounting method) of the sealing member 20 to the base 10.

The remaining effects of the semiconductor laser apparatus 220 are similar to those of the semiconductor laser apparatus 200.

### Third Embodiment

An optical pickup 300 according to a third embodiment of the present invention is now described. The optical pickup 300 is an example of the “optical apparatus” in the present invention.

The optical pickup 300 includes the semiconductor laser apparatus 210 according to the first modification of the second embodiment, an optical system 320 adjusting laser beams emitted from the semiconductor laser apparatus 210 and a light detection portion 330 receiving the laser beams, as shown in FIG. 12.

The optical system 320 has a polarizing beam splitter (PBS) 321, a collimator lens 322, a beam expander 323, a λ/4 plate 324, an objective lens 325, a cylindrical lens 326 and an optical axis correction device 327.

The PBS 321 totally transmits the laser beams emitted from the semiconductor laser apparatus 210, and totally reflects the laser beams fed back from an optical disc 340. The collimator lens 322 converts the laser beams emitted from the semiconductor laser apparatus 210 and transmitted through the PBS 321 to parallel beams. The beam expander 323 is constituted by a concave lens, a convex lens and an actuator (not shown). The actuator has a function of correcting wave surface states of the laser beams emitted from the semiconductor laser apparatus 210 by varying a distance between the concave lens and the convex lens in response to a servo signal from a servo circuit described later.

The λ/4 plate 324 converts the linearly polarized laser beams, substantially converted to the parallel beams by the collimator lens 322, to circularly polarized beams. Further, the λ/4 plate 324 converts the circularly polarized laser beams fed back from the optical disc 340 to linearly polarized beams. A direction of linear polarization in this case is orthogonal to a direction of linear polarization of the laser beams emitted from the semiconductor laser apparatus 210. Thus, the PBS 321 substantially totally reflects the laser beams fed back from the optical disc 340. The objective lens 325 converges the laser beams transmitted through the λ/4 plate 324 on a surface (recording layer) of the optical disc 340. An objective lens actuator (not shown) renders the objective lens 325 movable in a focus direction, a tracking direction and a tilt direction in response to servo signals (a tracking servo signal, a focus servo signal and a tilt servo signal) from the servo circuit described later.

The cylindrical lens 326, the optical axis correction device 327 and the light detection portion 330 are arranged to be along optical axes of the laser beams totally reflected by the PBS 321. The cylindrical lens 326 provides the incident laser beams with astigmatic action. The optical axis correction device 327 is constituted by a diffraction grating and so arranged that spots of zero-order diffracted beams of blue-violet, red and infrared laser beams transmitted through the cylindrical lens 326 coincide with each other on a detection region of the light detection portion 330 described later.

The light detection portion 330 outputs a playback signal on the basis of intensity distribution of the received laser beams. The light detection portion 330 has a detection region of a prescribed pattern, to obtain a focus error signal, a tracking error signal and a tilt error signal along with the playback signal. Thus, the optical pickup 300 including the semiconductor laser apparatus 210 is formed.

In this optical pickup 300, blue-violet, red and infrared laser beams are independently emitted from the blue-violet semiconductor laser chip 40, the red semiconductor laser chip 41 and the infrared semiconductor laser chip 42 sealed in the semiconductor laser apparatus 210. The laser beams emitted from the semiconductor laser apparatus 210 are adjusted by the PBS 321, the collimator lens 322, the beam expander 323, the λ/4 plate 324, the objective lens 325, the cylindrical lens 326 and the optical axis correction device 327 as described above, and thereafter applied onto the detection region of the light detection portion 330.

When data recorded in the optical disc 340 is play backed, the laser beam emitted from the semiconductor laser chip 40 (41, 42) selected depending on the type of the optical disc 340 is controlled to have constant power and applied to the recording layer of the optical disc 340, so that the playback signal output from the light detection portion 330 can be obtained. The actuator of the beam expander 323 and the objective lens actuator driving the objective lens 325 can be feedback-controlled by the focus error signal, the tracking error signal and the tilt error signal simultaneously output.

When data is recorded in the optical disc 340, the laser beam emitted from the semiconductor laser chip 40 (41, 42) selected depending on the type of the optical disc 340 is controlled in power on the basis of the data to be recorded and applied to the optical disc 340. Thus, the data can be recorded in the recording layer of the optical disc 340. Similarly to the above, the actuator of the beam expander 323 and the objective lens actuator driving the objective lens 325 can be feedback-controlled by the focus error signal, the tracking error signal and the tilt error signal output from the light detection portion 330.

Thus, the data can be recorded in or played back from the optical disc 340 with the optical pickup 300 including the semiconductor laser apparatus 210.

The optical pickup 300 includes the aforementioned semiconductor laser apparatus 210, and hence the low-cost and reliable optical pickup 300 capable of enduring the use for a long time can be obtained. The remaining effects of the optical pickup 300 are similar to those of the semiconductor laser apparatus 210.

Although the present invention has been described and illustrated in detail, it is clearly understood that the same is by way of illustration and example only and is not to be taken by way of limitation, the spirit and scope of the present invention being limited only by the terms of the appended claims.

For example, while the silicon resins 60 and 61 are formed between the adhesives 50 and 51 and the covering agents 70 and 71, respectively, in the semiconductor laser apparatus 100, the silicon resins 60 and 61 may not be formed therebetween. Alternatively, there may be clearances in regions where the silicon resins 60 and 61 are formed. Alternatively, the silicon resins 60 and 61 may be formed on openings of the through holes 11c and 11d (outside the package 30) in the rear surface 11b. The same is true in bonded regions where other members are bonded. Alternatively, resin made of another resin material such as rubber and having larger elasticity than the adhesives 50 and 51, for example, can be employed in place of silicon resin.

Bonded portions of all the members of the semiconductor laser apparatus may not be bonded with the adhesives, but part of the bonded portions may be bonded by conventional resistance welding or with kovar glass to be hermetically sealed. While the light transmission portion 21 and the sealing member 20 are bonded only with the covering agents 73 and 74 in the semiconductor laser apparatuses 200 and 210, the adhesives 53 and 54 may be employed together with the covering agents 73 and 74, similarly to the semiconductor laser apparatus 220.

A light curing or thermosetting material other than epoxy resin can be employed as the adhesives. A material with low water vapor permeability is preferably employed as the adhesives or an inorganic binder such as silica particles is preferably mixed in order to prevent entry of moisture into the package. Further, an oxide film of SiO₂, Al₂O₃ or the like or a metal film of Au, Ni, Cr or the like is more preferably formed as a gas barrier film on the surfaces of the adhesives. Thus, the EVOH resin can be prevented from absorbing moisture, and hence gas barrier properties can be prevented from decrease.

The wavelength of a laser beam emitted from the semiconductor laser chip may not be limited to the aforementioned wavelength, and semiconductor laser chips having another wavelengths may be combined and sealed also in the semiconductor laser apparatus 210 having the sealed different semiconductor laser chips. Three-wavelength laser beams of red (R), green (G) and blue (B), for example, are selected, whereby an RGB three-wavelength laser apparatus can be formed. Further, a projector or a display can be formed as an optical apparatus mounted with this RGB three-wavelength laser apparatus.

In addition to the aforementioned materials, an alloy of Al, Cu, Sn, Ni, stainless steel, Mg and the like can be employed as materials for the base, the lead frames and the sealing member. Ni-plated resin (polyphenylene sulfide, polyamide, a liquid crystal polymer or the like, for example) may be employed for the sealing member. Thus, the sealing member can be manufactured at a lower cost.

In addition to the aforementioned material, another type of glass or a translucent material can be employed as a material for the light transmission portion. A single layer or multilayer metal oxide film (dielectric film) of Al₂O₃, SiO₂, ZrO₂ or the like may be formed on the surface of the light transmission portion.

What is claimed is:

1. A semiconductor laser apparatus comprising:
a package having sealed space inside; and
a semiconductor laser chip arranged in said sealed space, wherein
said package has a first member and a second member bonded to each other with an adhesive,
a covering agent made of an ethylene-vinyl alcohol copolymer is formed on a bonded region of said first member and said second member in said sealed space, and
said adhesive is covered with said covering agent.

2. The semiconductor laser apparatus according to claim 1, wherein
said covering agent is arranged to be closer to said sealed space than said adhesive in said bonded region.

3. The semiconductor laser apparatus according to claim 1, wherein
said covering agent has a surface coming into contact with said sealed space, and said adhesive has a surface exposed to an outside of said package.

4. The semiconductor laser apparatus according to claim 1, wherein
said covering agent is arranged to come into contact with said adhesive and cover said adhesive.

5. The semiconductor laser apparatus according to claim 4, wherein
a contact interface between said covering agent and said adhesive is located on substantially the same plane as an outer surface of said package or located to be closer to said sealed space than said outer surface of said package.

6. The semiconductor laser apparatus according to claim 1, wherein
said covering agent continuously covers said adhesive along said bonded region of said first member and said second member not to expose said adhesive in said sealed space.

7. The semiconductor laser apparatus according to claim 1, wherein
resin having larger elasticity than said adhesive is arranged between said adhesive and said covering agent, and
said resin is covered with said covering agent.

8. The semiconductor laser apparatus according to claim 7, wherein
said resin having larger elasticity than said adhesive is sealed with said adhesive and said covering agent not to be exposed to an inside and an outside of said sealed space in said bonded region.

9. The semiconductor laser apparatus according to claim 7, wherein
said resin having larger elasticity than said adhesive is silicon resin.

10. The semiconductor laser apparatus according to claim 1, wherein
said first member and said second member are made of different materials.

11. The semiconductor laser apparatus according to claim 10, wherein
either said first member or said second member is made of metal while either said second member or said first member is made of glass, and
said first member and said second member are bonded to each other with said adhesive and said covering agent in said bonded region.

12. The semiconductor laser apparatus according to claim 1, wherein
said first member is transparent and bonded onto an opening of said second member,
a laser beam emitted from said semiconductor laser chip is transmitted through said first member and emitted to an outside of said package, and
said covering agent is formed on a bonded region of said second member and said first member other than said opening.

13. The semiconductor laser apparatus according to claim 12, wherein
said first member is bonded onto a surface of said second member in said sealed space of said package or a surface of said second member on the outside of said package opposite to said sealed space, and
said first member and said second member are bonded to each other with said adhesive and said covering agent arranged on a surface of said second member other than said opening.

14. The semiconductor laser apparatus according to claim 1, wherein
said first member has conductivity and is bonded onto an opening of said second member,
said first member is arranged to extend from an outside of said package to an inside of said sealed space in a state electrically isolated from said second member, and
said covering agent is formed in said opening of said second member.

15. The semiconductor laser apparatus according to claim 14, wherein
said first member is a lead frame,
said second member is a base for fixing said semiconductor laser chip in said sealed space,
said lead frame extends from said outside of said package to said inside of said sealed space in a state held in an opening of said base by said adhesive sealing said opening of said base, and
a surface of said adhesive in a portion on which said lead frame is mounted is covered with said covering agent in said sealed space.

16. The semiconductor laser apparatus according to claim 1, wherein
said first member is a sealing member sealing said package,
said second member is a base for fixing said semiconductor laser chip in said sealed space,
said sealing member and said base are bonded to each other with said adhesive, and
said covering agent covering said adhesive extends onto a surface of said sealing member other than said bonded region on a side bonded to said base.

17. The semiconductor laser apparatus according to claim 1, further comprising a photodetector arranged in said sealed space, monitoring intensity of a laser beam from said semiconductor laser chip, wherein
said photodetector is fixed in said sealed space through a conductive adhesive containing a volatile component, and
a surface of said conductive adhesive fixing said photodetector exposed in said sealed space is covered with said covering agent.

18. The semiconductor laser apparatus according to claim 1, wherein
said adhesive is made of a resin material containing a volatile component.

19. The semiconductor laser apparatus according to claim 1, wherein
said semiconductor laser chip includes a nitride-based semiconductor laser chip.

20. An optical apparatus comprising:
a semiconductor laser apparatus including a package having sealed space inside and a semiconductor laser chip arranged in said sealed space; and
an optical system controlling a beam emitted from said semiconductor laser chip, wherein
said package has a first member and a second member bonded to each other with an adhesive,
a covering agent made of an ethylene-vinyl alcohol copolymer is formed on a bonded region of said first member and said second member in said sealed space, and
said adhesive is covered with said covering agent.
